(19) United States
(12) Patent Application Publication
(10) Pub. No.: US 2009/0153365 A1
(43) Pub. Date: Jun. 18, 2009

(54) PORTABLE HAPTIC INTERFACE

(76) Inventors: Fabio Salsedo, Latina (IT); Massimo Bergamasoo, Castelmaggiore (IT); Antonio Frisoli, Pisa (IT); Guido Cini, S. Ermete (IT)

Correspondence Address: DENNISON, SCHULTZ & MACDONALD, 1727 KING STREET, SUITE 105, ALEXANDRIA, VA, 22314, US

(21) Appl. No.: 11/719,615

(22) PCT Filed: Nov. 18, 2005
(86) PCT No.: PCT/IB05/03460

§ 371 Date: Jun. 6, 2007

(30) Foreign Application Priority Data
Nov. 18, 2004 (IT) PI 2004A000084

(51) Int. Cl. H03K 17/94

(52) U.S. Cl. 341/20

(57) ABSTRACT

A portable interface device (1) of haptic human-computer type which can be fixed to a hand (2) of an operator (3), capable of engaging with the operator (3) transmitting on the operator's hand fingertips tactile sensations following the shape of a virtual surface (4), in particular obtained from a real surface (5). The tactile sensations are transmitted to a fingertip by the device (1) through a movable and orientable surface contacting the fingertip while remaining tangential to the virtual surface (4). The device (1), by touching the user's fingertip only at the points of contact with the virtual surface (4), does not provide to the user (3) any tactile sensations on the or on each fingertip when it moves in a free space, obtaining a very high level of transparency of the device. The workspace of the interface device (1) is very high, and can be also infinite, using suitable position tracking systems.

### DESCRIPTION

1. Field of the Invention

The present invention relates to a human-computer interface device.

In particular, the invention relates to a human-computer interface device of haptic type, i.e. capable of transmitting to an operator force and tactile sensations at the fingertips. Among the fields of application the following can be cited: entertainment, development of arts and culture, industrial design, education, marketing and on line sales of goods, telecommunication, etc.

2. Description of the Prior Art

As well known, virtual reality is a particular type of human-computer interaction, capable of creating a virtual environment in which the presence of objects is simulated by a computer. In fact, it is possible to use a computer for creating an environment with virtual walls and virtual surfaces of objects with which a user can interact by an interface device.

A haptic interface is a particular electromechanical device for improving the level of immersion of the user in the above described virtual reality, giving the impression. of touching the environment created by the computer.

Two cases of haptic interaction are commonly distinguished:
indirect interaction, when touching is mediated by a tool (for example a pen, a surgical scalpel);
direct interaction, when parts of the body of the operator touch directly the objects.

In case of simulation of an indirect haptic interaction, the presently known haptic interface devices have an end effector that is conformed as a tool, in order to stimulate in a realistic way tactile receptors of the operator. In case of simulation of direct interaction, the presently known haptic interface devices have end effectors, such as thimbles, handles etc., permanentely in contact with the operator. This condition has the drawback of negatively affecting a realistic stimulation of tactile receptors of the user. The user is, in fact, permanentenly in contact with an interface element of the device even when in the virtual space no contact with objects occurs.

Therefore, in the known systems it is not possible to generate a realistic perception of a transition between non contact and.contact, essential in case of a simulation of a gripping action or a tactile exploration of an object. In fact, the receptors on the fingertips of the user are already saturated by the presence of the haptic interface, which should, but is not, inherently transparent. Therefore, when the known systems are used for simulating direct interaction—for example recognizing the shape of an object by the fingertips—they provide unrealistic haptic sensations, comparable to those generated in a real environment when extraneous elements are held or worn, such as the thimbles.

Among known haptic interfaces, which aim to overcome the limits of the above described products, a device exist proposed by Y.Sato T. Yoshikawa Y. Yokokohji, N. Muramori: “Designing an encountered-type haptic display for multiple fingertip contacts based on the observation of human grasping behavior. In Proceedings of the 2004 IEEE International Conference on Robotics and Automation—New Orleans, La.—April 2004”. This device has movable surfaces that orient themselves as a plane tangential to the virtual object at the point of contact with the limb of the operator. The device has a base that is fixed with respect a workspace and is called “encountered interface”. It is based on the hypothesis that the recognition of the shape depends on the sensation of dragging the fingertips on the surface of the object and on the movement of the area of contact at the fingertip. Furthermore, it is based on the hypothesis that the recognition of the shape depends on the perception of the orientation of the surface of the object at the point of contact.

Such a haptic interface device has the drawback of requiring a calculation of the trajectory of the robotic device that must follow the user, by positioning the movable surfaces in suitable points of the space without interfering with the operator.

Further drawback is the dependence of the workspace of the device from the size of the virtual object. In particular, the simulation of a large device requires a correspondingly large workspace. Therefore the device is cumbersome and heavy, and also bulky and heavy are the actuators necessary to its operation.

### SUMMARY OF THE INVENTION

It is then a feature of the present invention to provide a haptic interface device suitable for recognizing virtual forms that is inherently transparent leaving a fingertip free of moving so that the fingertip can receive a realistic tactile sensation only when it reaches the points that belong to a virtual surface.

It is another feature of the present invention to provide a haptic interface device capable of simulating realistically the sensations on the fingertips that derive from the transition between a situation of not contact to a situation of contact and vice-versa.

A further feature of the invention is to provide a haptic interface device capable of transmitting to an operator an amount of tactile information data higher than traditional haptic interface devices.

Furthermore, it is a feature of the present invention to provide a haptic interface device capable of causing a user to perceive the local orientation of a virtual surface, in a remarkably shorter time than in the prior art.

Another feature of the invention is to provide a haptic interface device with encumbrance, weight and energy consumption that are reduced with respect to the known devices.

It is still a feature of the invention to provide a haptic interface device with shape and size such that it is easily portable, and in particular without any mechanical connections with a base of a support fixed with respect to the workspace, light, not much cumbersome and with low energy consumption.

A further feature of the invention is to provide a haptic portable interface device capable of being mounted on the structure of existing haptic interfaces, increasing the number of haptic information data transmitted to an operator.

These and other objects are achieved, according to the present invention, by a haptic portable interface device, which can be fixed to a hand in order to be integral to a finger, each finger having a fingertip, said device being characterised in that it comprises:
a connection element to said hand;
an orientable contact surface movably connected to said connection element and located near said fingertip;
means for spatially orienting said orientable surface about a point;
means for approaching/withdrawing said orientable surface to/from said fingertip;
means for detecting the spatial position and orientation of said connection element with respect to a fixed reference system;
means for defining a virtual surface;
means for operating said means for moving and said means for orienting responsive to said position and said orientation of said connection element with respect to said virtual surface.

In particular, said connection element is selected from the group comprised of:
at least one ring;
at least one tubular element;
at least one elastic band;
at least one tiable string.

In particular, said means for approaching/withdrawing said orientable surface comprises an articulation having a first end connected to said orientable surface and a second end pivotally connected to said support.

In particular, said at least one orientable contact surface belongs to an orientable plate.

This way, during the phase of free movement when the fingertip is not in contact with the virtual surface, said plate is kept at a distance from said user's fingertip, whereas during the transition between the non contact and contact with the virtual surface said plate is brought to touch said fingertip, assuming orientations of a plane tangential to the virtual surface in the point of contact.

This way, when moving in a free space, the user does not feel any tactile sensations on the fingertip, improving the rate of transparency of the device. Instead, when an interaction occurs with the virtual surface, tactile information is provided as presence, position and orientation of the area of contact and approaching direction of the fingertip with respect to the virtual object.

In particular, the approaching direction adds a realistic content to the tactile sensation, and this can be obtained causing the plate to approach the fingertip in the same relative approaching direction between fingertip and virtual surface.

Further advantage of the present invention is the workspace necessary to the movable surface with respect to the connection element that is in any case limited and independent from the size of the virtual object. Advantageously, said haptic interface device is mounted on several fingers of a hand, so that on each finger a corresponding haptic interface device operates. This way, using such a device for more fingers or a device for each finger of a hand, the user has a realistic sensation of the shape of a virtual object. Furthermore, since the plate touches the user only in case of actual contact in the virtual environment, in any desired circumstances the haptic interface device is completely transparent.

Preferably, said contact surface comprises a plurality of microactuators, said microactuators recreating completely the local geometry of said virtual surface. This way, said microactuators communicate to the user data concerning the local geometry of a simulated object, such as roughness and surface relief, giving sensations that are added to the already cited sensations of presence, position, orientation of the area of contact and approaching direction of the fingertip with respect to the virtual object.

In particular, said microactuators are tactile effectors.

In a preferred exemplary embodiment, said means for orienting said orientable surface comprises a parallel kinematic mechanism. In particular, said parallel kinematic mechanism provides:
a first and a second base link rotating about two respective perpendicular axes that are incident in a central point in said fingertip;
a first and a second connecting arm integral respectively to said first and second base links, said first arm having a free end running on a first circumference, said second arm having a free end running on a second circumference, said first and said second circumferences being two diametrical circumferences of a sphere with centre in said central point;
a connecting element having two free ends pivotally connected respectively to said free end of said first and second arms about two axes passing through said central point, said connecting element being integral to said orientable surface;
means for causing a rotation to said first and second base links;
a stiff support base for pivotally supporting said first and second base links.

This way, said orientable surface remains always tangential to a sphere with centre located in said central point.

In particular, said means for causing a rotation to said first and second base links comprises:
a substantially cylindrical surface integral and co-axial to each respective base link;
a flexible cable having an end connected to said cylindrical surface and wound on said cylindrical surface, suitable for causing a rotation to said cylindrical surface when pulled;
returning resilient means suitable for causing said cylindrical surface to return to an angular starting position when said flexible cable is released.

In particular, said returning resilient means comprises a torsion spring.

Preferably, said flexible cable is pulled by an electric motor located remotely from said haptic interface device.

In particular, said means for approaching/withdrawing said orientable surface to/from said fingertip comprises:
a fixed base integral to said connection element;
a base that is movable with respect to said fixed base, said movable base being integral to said stiff support base for pivotally supporting said first and second links of said means for orienting said orientable surface;
means for moving said movable base with respect to said fixed base.

Preferably, said means for moving said movable base with respect to said fixed base comprises a plurality of limbs connected between said fixed base and said movable base, said limbs moving said movable base changing its own length.

In particular, said limbs comprise:
a first link and a second link pivotally connected in series, wherein a first end of said first link is pivotally connected to said fixed base and a second end of said second link is pivotally connected to said movable base;
means for moving said second end with respect to said first end.

In particular, said means for moving said second end with respect to said first end comprises:
a flexible sheathed cable engaged to said second end and sliding in said first end suitable for approaching said second end to said first end when said cable is pulled;
elastic returning means.

Advantageously, said returning resilient means comprises a compression spring.

In particular, said fixed base is axially symmetric and concentric to said connection element.

In a preferred exemplary embodiment said movable base has substantially annular shape and is substantially concentric to said fixed base and said support element.

In particular, said plurality of limbs comprises three limbs arranged symmetrically with respect to the axis of said fixed base.

Advantageously, said means for detecting the spatial position and the orientation of said support, with respect to a reference system are selected from the group comprised of:
mechanical tracking means,
optical tracking means,
laser tracking means,
ultrasonic pulses tracking means,
infrared tracking means,
GPS tracking means, or combinations thereof.

### BRIEF DESCRIPTION OF THE DRAWINGS

The invention will be made clearer with the following description of some exemplary embodiments thereof, exemplifying but not limitative, with reference to the attached drawings wherein:

FIG. 1 shows an application of a haptic portable interface device according to the invention for virtually reproducing the contact sensation and with shape recognition of a virtual surface that repeates a real surface, for example of a statue;

FIG. 2 shows diagrammatically and in a simplified way an example of application of a haptic interface device according to the invention comprising five devices according to the invention, applied each to a finger of a hand;

FIG. 3 shows an analogy between the movement and the contact between a fingertip and a real surface and the movement and the contact between a fingertip and a virtual surface, obtained with a haptic interface device according to the invention;

FIG. 4 shows a simplified example of an exemplary embodiment of a haptic interface device according to the invention, having a passive arm capable of measuring continually the position of the haptic interface device with respect to an outer reference system;

FIG. 5 shows general view of an exemplary embodiment of an interface device according to the invention, operated by motors arranged remotely with respect to the interface device and connected to the same by means of corresponding sheathed flexible cables;

FIG. 6 shows a view of the above described haptic interface device of FIG. 5, comprising means for spatially orienting about a point an orientable surface and means for approaching/withdrawing this surface to/from a fingertip;.

FIG. 7 shows an unit of the haptic interface device of FIG. 5 capable of orienting the orientable surface;

FIGS. 8 and 9 show two views of another haptic interface device than that of FIG. 5, capable of approaching/withdrawing said orientable surface to/from said fingertip.

### DESCRIPTION OF PREFERRED EXEMPLARY EMBODIMENTS

In the following description, according to the invention, a human-computer interface device of haptic type is shown, i.e. capable of transmitting to an operator force and tactile sensations at the fingertips. More in detail the interface device is capable of orienting in space about a point an orientable surface and of approaching/withdrawing it to/from a fingertip, giving to an operator a tactile sensation to become aware of the shape of a virtual surface, in particular reproduced from a real surface. Furthermore, the haptic interface device, by touching the user's fingertip only at virtual points of contact with the real surface and reproducing a tangential orientation to this virtual surface in the point of contact, gives any tactile sensations on the fingertip during the motion in a free space, obtaining a very high level of transparency of the device. Furthermore, additional tactile sensations can be felt, such as the approaching direction, the orientation and the position of the area of contact and the relief of the surface. The workspace of the interface device can be very wide using suitable systems of position tracking.

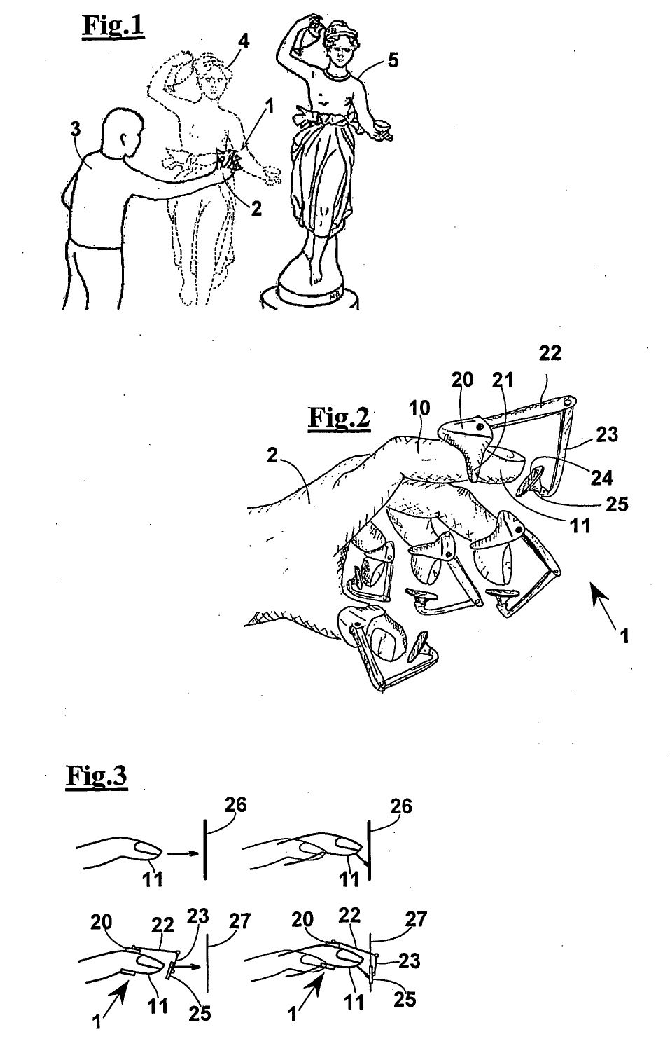

In FIG. 1 an exemplary embodiment is shown of a haptic portable interface device 1 according to the invention, put on the fingers of a hand 2 of an user 3, for virtually reproducing the contact sensation with a virtual surface 4 that repeates a real surface 5, for example a statue, acquired by electronic scanning.

More in detail, FIG. 2 shows diagrammatically and in a simplified way an example of a haptic interface device according to the invention comprising five alike devices 1, applied each to a finger 10 of a hand 2. Each device comprises a connection element 20 to a distal phalanx or fingertip 11 by means of an annular element 21, where the connection element 20 holds an articulation consisting of links 22 and 23 pivotally connected in series and have at a free end a plate 25 with an orientable surface 24.

FIG. 3 shows an analogy between the movement and the contact between a fingertip 11 and a real surface 26 as well as the movement and the contact between a fingertip 11 and a virtual surface 27, obtained with a haptic interface device 1 according to the invention, having a connection element 20, an articulation consisting of links 22 and 23 and a plate 25.

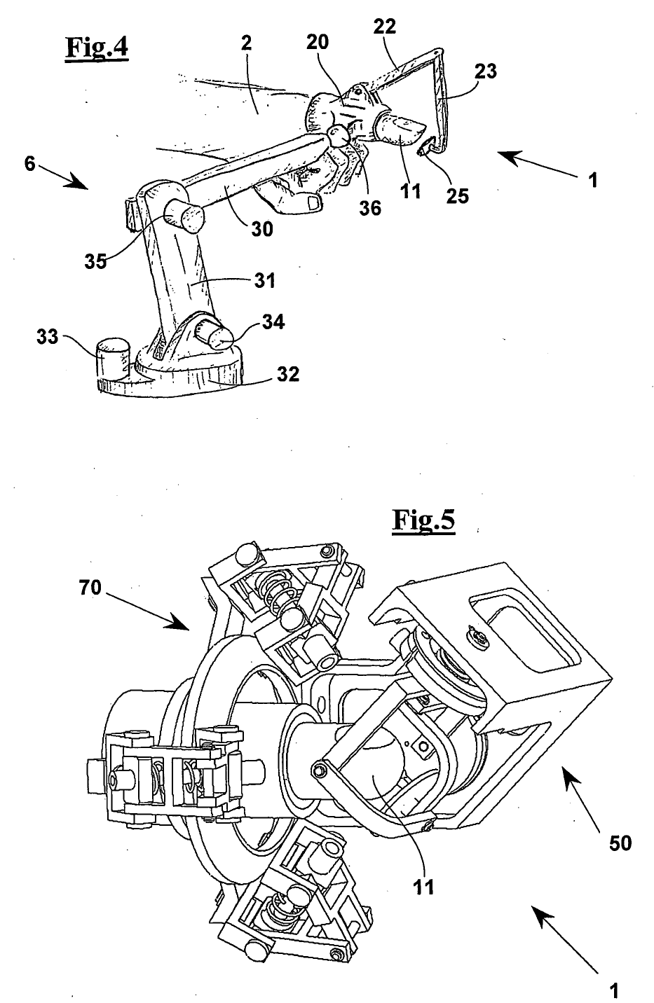

FIG. 4 shows a simplified example of haptic interface device 1 according to the invention, connected to a passive articulation 6 capable of measuring continually the position of the haptic interface device 1 with respect to a outer reference system. In this case the haptic interface device has a connection element 20 connected to the free end of the articulation 6, by a sphere joint 36. Articulation 6, for example, can comprise a rotational coupling 33, 34, 35 and joints 32, 31, 30 mounted in series.

FIG. 5 shows general view of an exemplary embodiment of an interface device 1 according to the invention, operated by a motors unit 40 arranged remotely with respect to interface device 1 and connected to the same by means of corresponding sheathed flexible cables indicated with 42 and 43. In particular, sheathed cables 42 operate the joints 80 described hereinafter of the means 50 for approaching/withdrawing the surface 25 to/from the fingertip 11 and the sheathed cables 43 operate the means 50 for orienting the orientable surface 25 with respect to the fingertip.

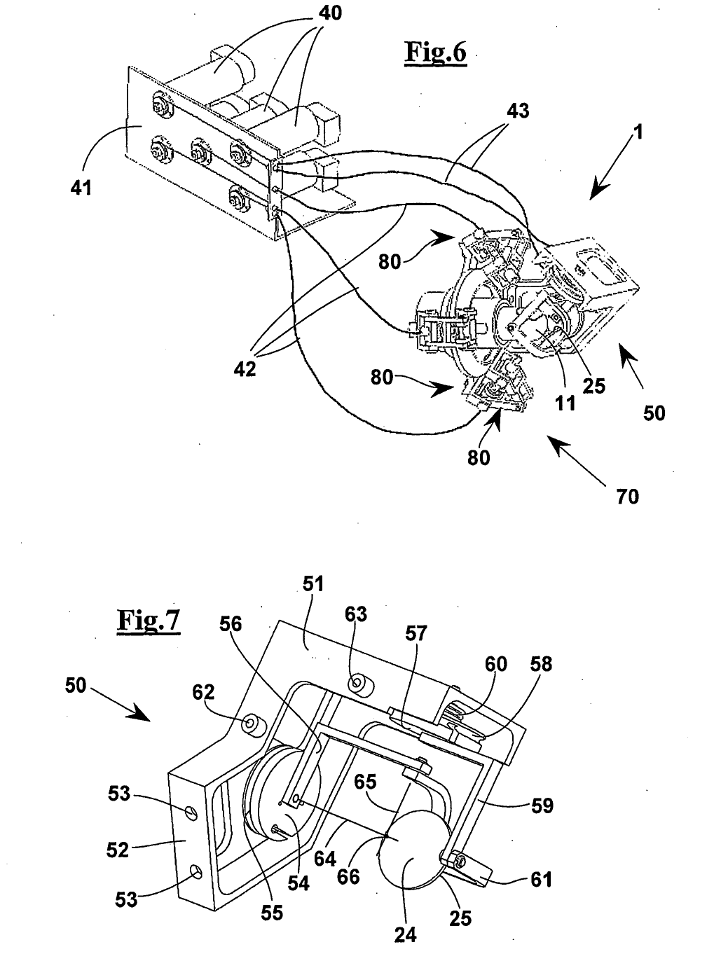

FIG. 6 shows a view of the above described haptic interface device 1, comprising means 50 for spatially orienting and about a point an orientable surface 24 and means 70 for approaching/withdrawing this surface to/from a fingertip 11.

FIG. 7 shows an exemplary embodiment of means 50 for orienting the surface 24 of the orientable plate 25 about a point 66. In an exemplary embodiment shown in the figure, the means for orienting 50 forms a parallel kinematic mechanism having: a first base link 54 and a second base link 58 rotating about two respective perpendicular axes 64 and 65 that are incident in a central point 66 in said fingertip; a first connecting arm 56 and a second.connecting arm 59 integral respectively to said first and second base links 54 and 58; a connecting element 61 having two free ends pivotally connected respectively to said free end of said first and second arms 56 and 59 about two axes 64 and 65 passing through said central point 66, said connecting element 61 being integral to said orientable surface 24; a stiff base 51 of support for pivotally supporting said first and second base links.

This way, the orientable surface 24 remains always tangential to a sphere not shown with centre located in said central point 66.

The above described base link comprises: a substantially cylindrical lateral surface, respectively indicated as 55 and 58, co-axial and integral to each respective base link; a flexible cable not shown in the figure, connected and partially wound on this surface 55 and 58; the corresponding base link when this cable is pulled; and a torsion spring suitable for causing the base link to return in the respective starting position when the cable is released.

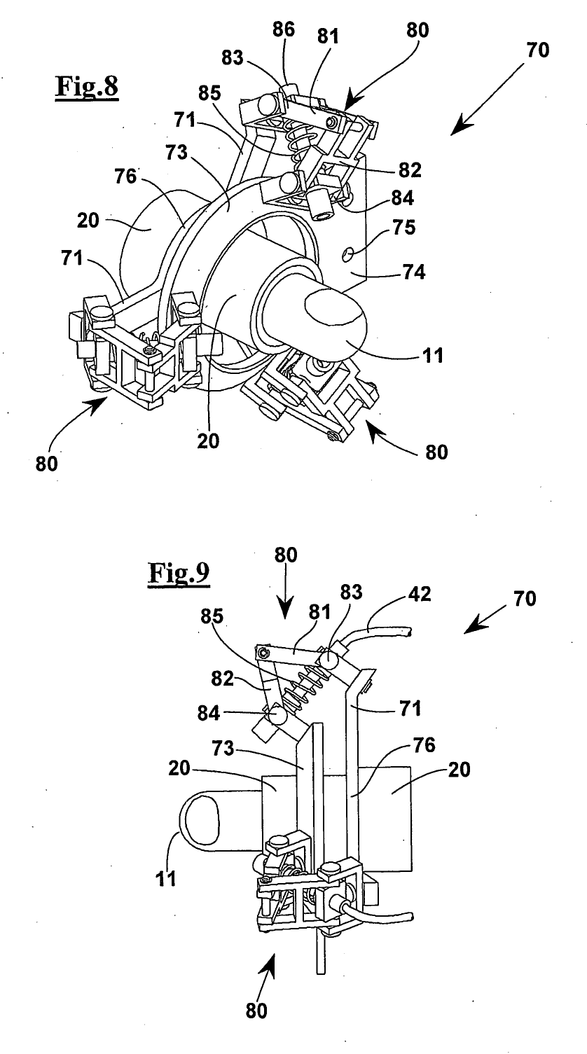

FIGS. 8 and 9 show two perspective views of means 70 for approaching/withdrawing the above described orientable surface, not shown in the figure, to/from said fingertip. In particular, said means 70 for approaching/withdrawing said orientable surface to/from said fingertip comprises a fixed base 76 integral to said connection element 20, a base that is movable 73 with respect to said fixed base 76, said movable base 76 being integral to said stiff support base 51 shown in FIG. 7. The means 70, furthermore, comprises three limbs 80 connected according to a central symmetry between said fixed base 76 and said movable base 73, said limbs 80 moving said movable base 73 changing its own length. In particular, said limbs 80 comprise a first link 81 and a second link 82 pivotally connected in series, wherein a first end 83 of said first link 81 is pivotally connected to said fixed base 76 and a second end 84 of said second link 82 is pivotally connected to said movable base 73. The articulation 80, furthermore, comprises a flexible sheathed cable 42 engaged to said second end 84 and sliding in said first end 83 suitable for approaching said second end 84 to said first end 83 when said cable 42 is pulled, as well as a compression spring for. elastic return. In particular, in the case described in the figure, the fixed base 76 is axially symmetric and concentric to said connection element 20. Furthermore, said movable base 73 has substantially annular shape and is substantially concentric to said fixed base 76 and said support element 20.

In a structural form of the invention, that a skilled person can reach using normal experience, the many actuating links can be arranged in order to have positions of minimum encumbrance for a user.

Notwithstanding, furthermore, the annular support to the finger is put on distal phalanxes, it is not excluded that it is mounted elsewhere, for example on the palm of a hand, at the wrist, etc. In this case the support and the fingertip should be integral to each other.

Concerning the tracking system, it can be of the type with stiff articulated links, as shown in FIG. 6, or it can be wireless, as in FIG. 1. In general, they can be of mechanical, optical, laser, ultrasonic pulses or electromagnetic types, using known systems and then not described in detail.

The foregoing description of a specific embodiment will so fully reveal the invention according to the conceptual point of view, so that others, by applying current knowledge, will be able to modify and/or adapt for various applications such an embodiment without further research and without parting from the invention, and it is therefore to be understood that such adaptations and modifications will have to be considered as equivalent to the specific embodiment. The means and the materials to realise the different functions described herein could have a different nature without, for this reason, departing from the field of. the invention. It is to be understood that the phraseology or terminology employed herein is for the purpose of description and not of limitation.

1. A haptic portable interface device, which can be fixed to a hand in order to be integral to a finger, each finger having a fingertip, said device being characterised in that it comprises:
a connection element to said hand;
an orientable contact surface movably connected to said connection element and located near said fingertip;
means for spatially orienting said orientable surface about a point;
means for approaching/withdrawing said orientable surface to/from said fingertip;
means for detecting the spatial position and the orientation of said connection element with respect to a fixed reference system;
means for defining a virtual surface;
means for operating said means for moving and said means for orienting responsive to said position and said orientation of said connection element with respect to said virtual surface.

2. Haptic portable interface device, according to claim 1, wherein said connection element to said hand is selected from the group comprised of:
at least one ring for fastening to a finger;
at least one tubular element;
at least one elastic band;
at least one tiable string.

3. Haptic portable interface device, according to claim 1, wherein said means for approaching/withdrawing said orientable surface comprises a connecting articulation having a first end connected to said orientable surface and a second end pivotally connected to said connection element.

4. Haptic portable interface device, according to claim 1, wherein said at least one orientable contact surface belongs to a orientable plate.

5. Haptic portable interface device, according to claim 1, wherein said haptic interface device is mounted on several fingers of a hand, so that each finger cooperates with a corresponding haptic interface device.

6. Haptic portable interface device, according to claim 1, wherein said contact surface comprises a plurality of microactuators, said microactuators recreating completely the local geometry of said virtual surface, and, in particular said microactuators are tactile effectors.

7. Haptic portable interface device, according to claim 1, wherein said means for orienting said orientable surface comprises a parallel kinematic mechanism.

8. Haptic portable interface device, according to claim 7, wherein said parallel kinematic mechanism provides:
a first and a second base link rotating about two respective perpendicular axes that are incident in a central point in said fingertip;
a first and a second connecting arm integral respectively to said first and second base links, said first arm having a free end running on a first circumference, said second arm having a free end running on a second circumference, said first and said second circumferences being two diametrical circumferences of a sphere with centre in said central point;
a connecting element having two free ends pivotally connected respectively to said free end of said first and second arms about two axes passing through said central point, said connecting element being integral to said orientable surface;
means for causing a rotation to said first and second base links;
a stiff support base for pivotally supporting said first and second base links.

9. Haptic portable interface device, according to claim 8, wherein said means for causing a rotation to said first and second base links comprises:
a substantially cylindrical surface integral and co-axial to each respective base link;
a flexible cable having an end connected to said cylindrical surface and wound on said cylindrical surface, suitable for causing a rotation to said cylindrical surface when pulled;
returning resilient means suitable for causing said cylindrical surface to return to an angular starting position when said flexible cable is released.

10. Haptic portable interface device, according to claim 1, wherein said means for approaching/withdrawing said orientable surface to/from said fingertip comprises:
a fixed base integral to said connection element;
a base that is movable with respect to said fixed base, said movable base being integral to said stiff support base for pivotally supporting said first and second links of said means for orienting said orientable surface;
means for moving said movable base with respect to said fixed base.

11. Haptic portable interface device, according to claim 10, wherein said means for moving said movable base with respect to said fixed base comprises a plurality of limbs connected between said fixed base and said movable base, said limbs moving said movable base changing its own length.

12. Haptic portable interface device, according to claim 11, wherein said limbs comprise:
a first link and a second link pivotally connected in series, wherein a first end of said first link is pivotally connected to said fixed base and a second end of said second link is pivotally connected to said movable base;
means for moving said second end with respect to said first end.

13. Haptic portable interface device, according to claim 12, wherein said means for moving said second end with respect to said first end comprises:
a flexible sheathed cable engaged to said second end and sliding in said first end suitable for approaching said second end to said first end when said cable is pulled;
elastic returning means.

14. Haptic portable interface device, according to claim 1, wherein said returning resilient means comprises a compression spring.

15. Haptic portable interface device, according to claim 1, wherein said means for detecting the spatial position and the orientation of said support with respect to a reference system are selected from the group comprised of:
mechanical tracking means,
optical tracking means,
laser tracking means,
ultrasonic pulses tracking means,
infrared tracking means,
GPS tracking means,
a combination of said tracking means.
